(19) United States
(12) Patent Application Publication
(10) Pub. No.: US 2012/0088318 A1
(43) Pub. Date: Apr. 12, 2012

(54) Method for Fabricating a Vertical Light-Emitting Diode with High Brightness

(75) Inventors: Hsiang-Szu CHANG, Yangmei City (TW); Nien-Tze YEH, Zhongli City (TW); Kuen-Pu LU, Xinzhuang City (TW); Chao-Cheng WANG, Nantou City (TW)

(73) Assignee: TEKCORE CO., LTD., Nantou (TW)

(21) Appl. No.: 13/269,658

(22) Filed: Oct. 10, 2011

(30) Foreign Application Priority Data
Oct. 12, 2010 (TW) 099134805

(51) Int. Cl. H01L 33/48

(52) U.S. Cl. 438/26; 257/E33.056

(57) ABSTRACT

A method for fabricating a vertical light-emitting diode comprises forming a stack including a plurality of epitaxial layers on a patterned first substrate, placing a second substrate on the stack, removing the first substrate to expose the first surface, planarizing a first surface of the stack that was in contact with the patterned first substrate and has a pattern corresponding to a pattern provided on the first substrate to form a planarized second surface, and forming a first electrode in contact with a side of the second substrate that is opposite to the stack, and a second electrode in contact with the second surface of the stack. A roughening step can be performed to form uneven surface portions on a region of the second surface for improving light emission through the second surface of the stack.

### CROSS-REFERENCE TO RELATED APPLICATION

This application claims priority to Taiwan Patent Application No. 099134805, filed on Oct. 12, 2010.

### BACKGROUND OF THE INVENTION

1. Field of the Invention

The present invention relates to methods for fabricating a light-emitting diode, and more particularly to a method for fabricating a vertical light-emitting diode that has high brightness.

2. Description of the Related Art

Light-emitting diodes (LED) are widely used in lighting devices and display devices. In a conventional process for fabricating a light-emitting diode, the multilayered light-emitting structure is epitaxially grown on a sapphire substrate. Owing to the low electrical conduction and thermal dissipation of the sapphire substrate, two electrodes may be formed on the same side of the light-emitting diode to form a horizontal type light-emitting diode. However, the lateral light-emitting diode has certain disadvantages, including current crowding effect and high forward voltage. Accordingly, the horizontal type light-emitting diode may have poor efficiency and output power.

In order to overcome the disadvantages of low electrical conduction and thermal dissipation, one approach proposes the structure of a vertical light-emitting diode. In a vertical type light-emitting diode, the two electrodes are disposed on the top of light-emitting structure and the back side of the substrate, respectively. To fabricate the vertical type light-emitting diode, a buffer layer is first formed on a sapphire substrate. Nitride semiconductor compounds can be then grown on the buffer layer to form the light-emitting structure. A conductive substrate (such as a metal substrate) then can be placed on the light-emitting structure, followed with the removal of the sapphire substrate. Electrodes then can be formed on the back side of the conductive substrate and the top of the light-emitting structure, respectively.

Certain approaches have been proposed to improve the process of fabricating a vertical light-emitting diode, such as described in Taiwan Pat. No. 1294700, Taiwan patent No. 1293813, Taiwan application publication No. TW201010127, Taiwan patent No. 1304660, and Taiwan patent No. 1315915, the disclosure of which is incorporated herein by reference. Taiwan patent No. 1294700 relates to a light-emitting structure in which a second clad layer with an uneven thickness is used to adjust the electrical resistance to equilibrium, so that the light can be emitted uniformly. Taiwan patent No. 1293813 discloses using an adhering reflection layer to improve the binding between the light-emitting structure and the supporting substrate, and enhance emission efficiency. Taiwan application publication No. TW201010127 discloses binding the supporting substrate with a conductive adhesive to prevent epitaxial fracture that may be induced by the removal of the sapphire substrate via laser lift-off. The disclosure of Taiwan patent No. 1304660 relates to the use of chip-bonding in the manufacture of a vertical light-emitting diode. Taiwan patent No. 1315915 discloses that a fabrication method in which a second semiconductor layer is formed on a second substrate having an indentation structure, and an electrode is then formed on a corresponding indentation structure of the semiconductor layer.

In the aforementioned manufacture methods, point defect or line defect of the epitaxial layer may easily occur because the lattice constant and the coefficient of thermal expansion of the nitride compound differ from those of the sapphire substrate. Such defects may adversely affect the characteristics of the light-emitting diode, such as reduced brightness, and larger input current to achieve similar output efficiency. Therefore, there is a need for a method fabricating a vertical light-emitting diode that can address at least the foregoing issues.

### SUMMARY

The present application describes a method for fabricating a vertical light-emitting diode. In some embodiments, the method comprises forming a stack including a plurality of epitaxial layers on a patterned first substrate, placing a second substrate on the stack, removing the first substrate to expose the first surface, planarizing a first surface of the stack that was in contact with the patterned first substrate and has a pattern corresponding to a pattern provided on the first substrate to form a planarized second surface, and forming a first electrode in contact with a side of the second substrate that is opposite to the stack, and a second electrode in contact with the second surface of the stack. A roughening step can be performed to form uneven patterns on a portion of the second surface c for improving light emission through the second surface of the stack.

### BRIEF DESCRIPTION OF THE DRAWINGS

FIGS. 1A-1F are schematic views illustrating intermediary stages in the fabrication of a vertical light-emitting diode;

FIG. 2 is a schematic view illustrating another embodiment of a method for fabricating a vertical light-emitting diode; and

FIG. 3 illustrates various geometrical shapes of the pattern provided on a sapphire substrate.

### DETAILED DESCRIPTION OF THE EMBODIMENTS

The present application describes a method for fabricating a vertical light-emitting diode comprised of a stack of multiple epitaxial layers. The stack of the epitaxial layers can be formed on a patterned surface of a sapphire substrate. After the substrate is removed, planarization can be applied on the surface of the stack that was in contact with the patterned surface of the sapphire substrate, and an electrode layer then can be formed on the planarized surface of the stack. A roughening step can also be performed to form uneven patterns on a portion of the second surface for improving light emission through the second surface of the stack. The method described herein can be applied to fabricate various vertical light-emitting diodes, especially vertical light-emitting diodes with high brightness.

“Group III nitride” as employed herein can refer to a compound that contains nitrogen (N) and a chemical element belonging to the group III of the periodic table such as aluminum (Al), gallium (Ga), indium (In) and the like, as well as any compound thereof (such as AlGaN, AlInGaN). In one embodiment, AlₓIn_{y}Ga_{1-x-y}N (0≦x≦1, 0≦y≦1) or oxide semiconductor material can be incorporated in the multilayer stack of the light-emitting diode.

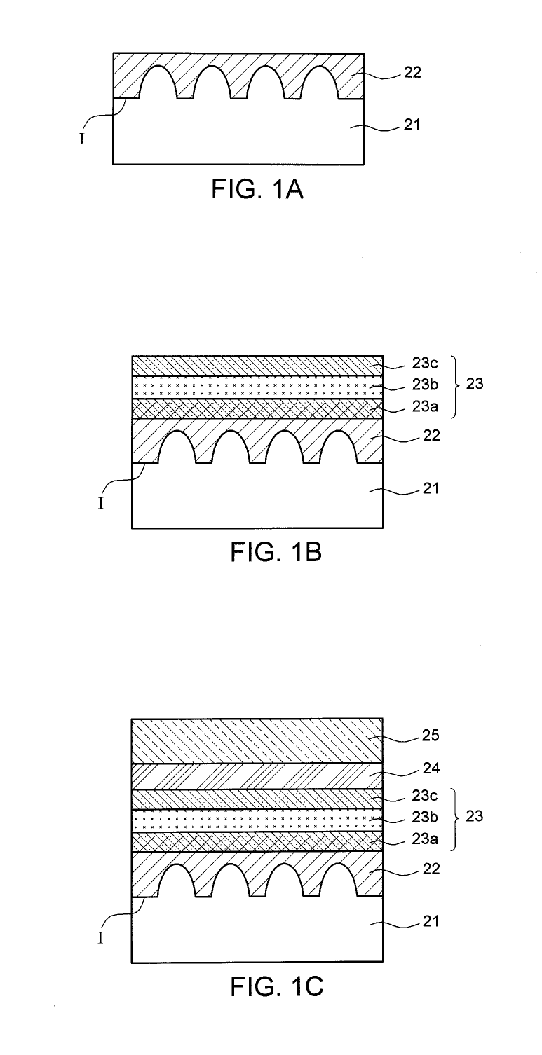

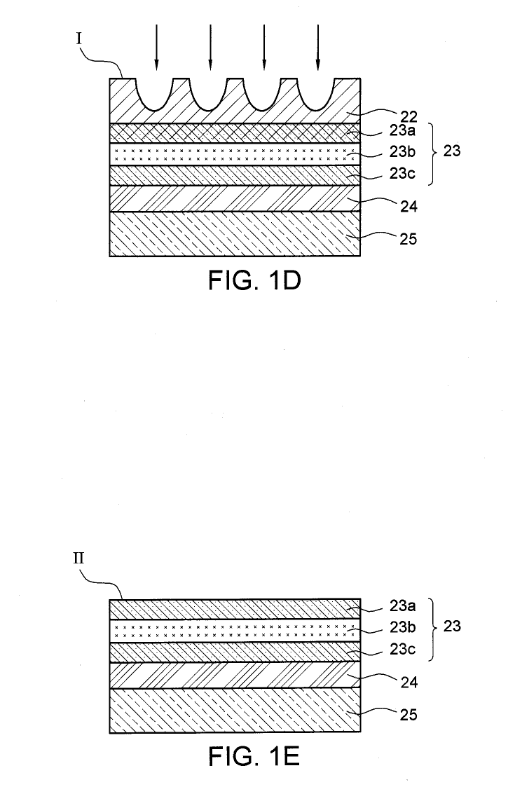

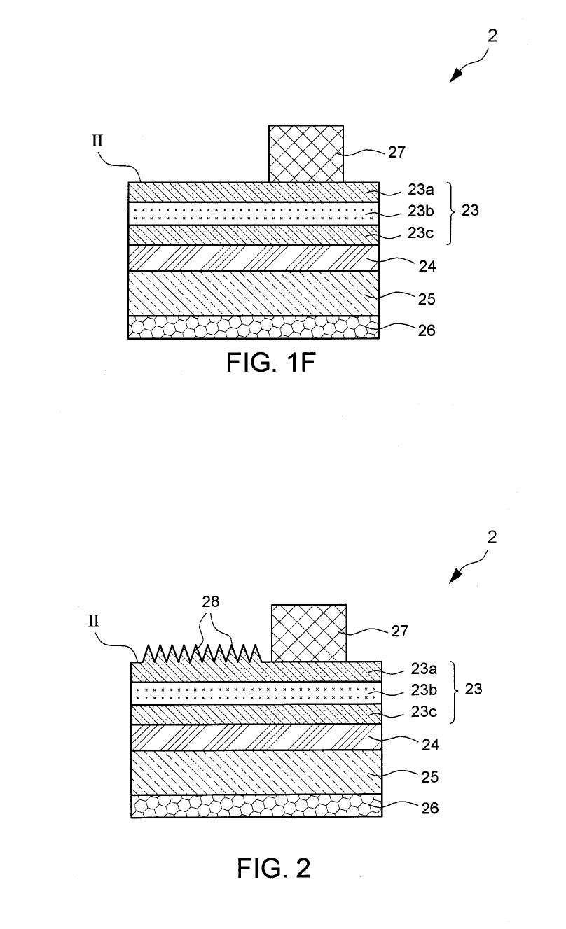

FIGS. 1A through 1F are schematic views illustrating intermediary stages in the fabrication of a vertical light-emitting diode. Referring to FIG. 1A, a sapphire substrate 21 can be first provided. The sapphire substrate 21 can have a surface that is treated to form a pattern thereon. A buffer layer 22 made of a group III nitride compound (such as GaN) can be formed on the patterned surface of the sapphire substrate 21. The formed buffer layer 22 can have a surface I in contact with the sapphire substrate 21.

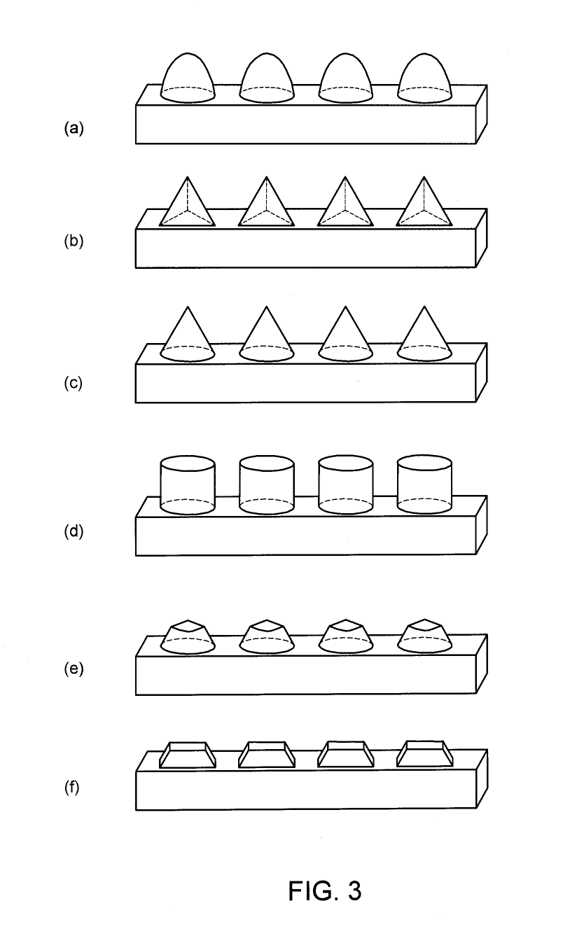

The patterned surface of the sapphire substrate 21 on which is formed the buffer layer 22 can be provided with a pattern of various geometrical shapes including, without limitation, pyramid shapes, posts, half lenticular or concave or convex shapes, conical shapes and the like. These patterns can be formed as projections including tapered profiles, non-tapered profiles or a combination thereof. FIG. 3 illustrates different examples of patterns including, without limitation, smooth half-oval (as shown in (a) of FIG. 3), pyramid shapes (as shown in (b) of FIG. 3), cones (as shown in (c) of FIG. 3), truncated cones (as shown in (e) of FIG. 3), truncated pyramids (as shown in (f) of FIG. 3) and the like. Non-tapered patterns can include pillar shapes, such as shown in (d) of FIG. 3. It will be appreciated that the patterned surface of the sapphire substrate 21 is not limited to the foregoing examples of shapes, and other geometry may be applicable.

The patterned surface of the sapphire substrate 21 can significantly reduce a defect density in the epitaxial layers formed thereon, and enhance the properties of the light-emitting diode. The protruding shapes patterned from the surface of the sapphire substrate 21 can result in the first surface I of the buffer layer 22 being formed with corresponding recessed and protruding shapes. The buffer layer 22 can be an epitaxial layer formed by metal-organic chemical vapor deposition (MOCVD) or molecular beam epitaxy (MBE).

Next referring to FIG. 1B, a multilayered light-emitting structure 23 comprised of multiple epitaxial layers can be formed on the buffer layer 22. The multilayered light-emitting structure 23 can be formed by MOCVD or MBE, and include group III nitride semiconductor materials and/or oxide semiconductor materials. In one embodiment, the multilayered light-emitting structure 23 can include a n-GaN layer 23a, a light-emitting layer 23b and a p-GaN layer 23c respectively stacked on the buffer layer 22. In one embodiment, the light-emitting layer 23b can be formed as a structure of multiple quantum well (MQW) layers.

Next referring to FIG. 1C, a bonding layer 24 can be formed on the p-GaN layer 23c, and a conductive substrate 25 then can be attached onto the bonding metal layer 24. The bonding layer 24 can be made of a metallic material. The above buffer layer 22, multilayered light-emitting structure 23, bonding layer 24 and conductive substrate can be grown/assembled in accordance with any known methods.

Next referring to FIG. 1D, the sapphire substrate 21 can be removed from the first surface I. Methods applied for removing the sapphire substrate 21 can include laser lift-off, etching or polishing. In one embodiment, laser lift-off can be preferably used. KrF excimer laser with a wavelength of 248 nm can be applied on the side of the sapphire substrate 21 so that dissociation at the portion of the buffer layer 22 near the sapphire substrate 21 can occur. Then, heating can be applied at a temperature between about 30-40° C. to peel the sapphire substrate 21. As a result, the first surface I can be exposed with a pattern of shapes corresponding to the patterned surface of the sapphire substrate 21.

The uneven profile of the first surface I may cause total internal reflection (TIR), which can result in reduced light extraction and increased heating in the light-emitting diode. A surface treatment can be conducted to planarize the first surface I after removal of the sapphire substrate 21.

Referring to FIGS. 1D and 1E, a planarization step can be applied on the stack of epitaxial layers. Selective wet etching or polishing can be conducted to planarize the first surface I. In one embodiment, the stack of epitaxial layers can be cleaned and immersed in an etching agent at a temperature between about 20-200° C. Through planarization, the first surface I can be converted into a planarized surface II. Subsequently, the etching agent can be removed, and the stack of epitaxial layers can be rinsed in an organic solution (such as acetone, methanol, isopropanol or ethanol).

In the aforementioned planarization step, the used etching agent can selectively etch a nitride semiconductor material. In some embodiments, the etching agent can be an acid solution selected from H₂SO₄, H₃PO₄, HNO₃, HNO₂, H₃PO₃, HCl, CH₃COOH, H₂CO₃, H₂BO₃, HCOOH, HIO₃, H₂C₂O₄, HF, H₂S, H₂SO₃, HSO₃F, RSO₃F (R═CₙH₂ₙ₊₁), or any mixture thereof. In other embodiments, the etching agent can be an alkaline solution selected from NaOH, KOH, Ca(OH)₂, TMAH, NH₄OH, Na₂CO₃, NaHCO₃, K₂CO₃, Ba(OH)₂, or any mixture thereof. The etching agent (acidic solution or alkaline solution) can exhibit a high etching rate with respect to an uneven or unsmooth surface of a nitride semiconductor material, and almost no etching or extremely low etching rate with respect to a flat surface of a nitride semiconductor material. Accordingly, the coarse profile of the first surface I can be effectively planarized with the etching agent. It is worth noting that because the buffer layer 22 is relatively thin, it may be completely removed after planarization. Accordingly, the planarized surface II can be defined as a surface of the n-GaN layer 23a.

Next referring to FIG. 1F, a first electrode 26 can be formed on an exposed side of the conductive substrate 25 opposite to the side of the planarized surface II, and a second electrode 27 can be formed on the planarized surface II of the multilayered light-emitting structure 23 (e.g., on the top of the n-GaN layer 23a). The first electrode 26 and the second electrode 27 can be formed in contact with the conductive substrate 25 and the n-GaN layer 23a, respectively. As a result, the structure of a vertical light-emitting diode 2 can be formed.

With reference to FIG. 2, another embodiment can apply additional processing steps on the vertical light-emitting diode 2. After formation of the first electrode 26 and second electrode 27, the second surface II of the multilayered light-emitting structure 23 can be at least partially roughened to form a region comprised of uneven surface portions 28. Examples of geometrical shapes for the uneven surface portions 28 can include, without limitation, pyramid, cone, half-lenticular shapes and the like. Chemical etching or dry etching can be used to roughen an area of the planarized surface II of the n-GaN layer 23a to form the region of the uneven surface portions 28 apart from the area of the second electrode 27. The chemical etching agent be selected from H₂O₂, KOH, TMAH, or any combination thereof, such as a mixture of KOH and TMAH. The composition ratio of the etching agent can be adjusted with the desired etching conditions.

In one embodiment, a two-stage surface treatment can be implemented. After formation of the first electrode 26 and second electrode 27, the stack of layers can be cleaned with an organic solution (such as acetone, methanol, isopropanol or ethanol), and then immersed in a chemical etching agent at a temperature between about 20° C. and 200° C. The chemical etching agent can be a solution mixture of KOH and TMAH. After a period of time, the stack of layers can be retrieved and rinsed via an organic solution. The stack of layers then can perform a second etching step with the same chemical etching agent as in the first stage and in the same conditions. Subsequently, the stack of layers can be rinsed with an organic solution. As shown in FIG. 2, the vertical light-emitting diode 2 formed after the aforementioned two-stage surface treatment can include the region of the uneven surface portions 28 that is apart from the area of the second electrode 27. The region with the uneven surface portions 28 can differ from the pattern of the sapphire substrate 21 (e.g., height of the uneven surface portions, density, shape, etc.). With this construction, light exiting the light-emitting diode can be scattered in a more efficient manner.

In the method described herein, the use of the patterned sapphire substrate can significantly reduce the defect density of the stacked epitaxial layers, and improve the properties of light-emitting diode. After the sapphire substrate is removed, the uneven surface of the stack of epitaxial layers initially facing the sapphire substrate (as shown in FIGS. 1C and 1D) can perform a planarization step to prevent the occurrence of total internal reflection.

In addition, a roughening step can be performed to form the region of the uneven surface portions 28 that act to efficiently scatter light out of the light-emitting diode. Examples of shapes for the uneven surface portions 28 can include, without limitation, pyramids, cones, and/or half lenticular shapes. Depending on the size and number of the uneven surface portions, the emission efficiency of light-emitting diode can be increased by at least 5% to 10%. In other embodiments, the uneven surface portions 28 may also differ from that shown in FIG. 3 to increase the emission efficiency of the light-emitting diode.

Realizations in accordance with the present invention therefore have been described only in the context of particular embodiments. These embodiments are meant to be illustrative and not limiting. Many variations, modifications, additions, and improvements are possible. Accordingly, plural instances may be provided for components described herein as a single instance. Structures and functionality presented as discrete components in the exemplary configurations may be implemented as a combined structure or component. These and other variations, modifications, additions, and improvements may fall within the scope of the invention as defined in the claims that follow.

What is claimed is:

1. A method for fabricating a vertical light-emitting diode comprising:
forming a stack including a plurality of epitaxial layers on a patterned first sapphire substrate, wherein the stack has a first surface in contact with the patterned first substrate, the first surface including a pattern corresponding to a pattern provided on the first substrate;
placing a second substrate on the stack;
removing the first substrate to expose the first surface;
planarizing the first surface to remove the pattern and form a planarized second surface of the stack; and
forming a first electrode in contact with a side of the second substrate that is opposite to the stack, and a second electrode in contact with the second surface.

2. The method of claim 1, wherein the stack comprises any of a AlₓIn_{y}Ga_{1-x-y}N (0≦x≦1, 0≦y≦1) semiconductor material and a oxide semiconductor material.

3. The method of claim 1, wherein the second substrate is placed on the stack of the epitaxial layers by wafer bonding.

4. The method of claim 1, wherein the first sapphire substrate is removed by laser lift-off, dry etching, wet etching or polishing.

5. The method of claim 1, wherein the step of planarizing the first surface is performed by applying selective wet etching.

6. The method of claim 5, wherein the selective wet etching includes an etching agent comprising an acidic solution or an alkaline solution, the acidic solution being a solution of an acid or a mixture of acids, and the alkaline solution being a solution of a base or a mixture of base agents.

7. The method of claim 6, wherein the acidic solution includes sulfuric acid (H₂SO₄), phosphoric acid (H₃PO₄), nitric acid (HNO₃), nitrous acid (HNO₂), phosphorous acid (H₃PO₃), hydrochloric acid (HCl), acetic acid (CH₃COOH), carbonic acid (H₂CO₃), boric acid (H₂BO₃), formic acid (HCOOH), iodic acid (HIO₃), oxalic acid (H₂C₂O₄), hydrofluoric acid (HF), hydrosulfuric acid (H₂S), sulfurous acid (H₂SO₃), fluorosulfonic acid (HSO₃F), alkylsulfonic acid (RSO₃F, R═CₙH₂ₙ₊₁), or any mixture thereof.

8. The method of claim 6, wherein the alkaline solution includes sodium hydroxide (NaOH), potassium hydroxide (KOH), calcium hydroxide (Ca(OH)₂), tetramethylammonium hydroxide (TMAH), ammonium hydroxide (NH₄OH), sodium carbonate (Na₂CO₃), sodium hydrogen carbonate (NaHCO₃), potassium carbonate (K₂CO₃), barium hydroxide (Ba(OH)₂), or any mixture thereof.

9. The method of claim 1, wherein the step of planarizing the first sapphire surface is performed by polishing.

10. The method of claim 1, further comprising roughening the second surface after the first and the second electrodes are formed.

11. The method of claim 10, wherein the step of roughening the second surface is performed by chemical etching or dry etching.

12. The method of claim 11, wherein the chemical etching uses an etching agent selected from an acid or a base, the acid including sulfuric acid (H₂SO₄), phosphoric acid (H₃PO₄), nitric acid (HNO₃), nitrous acid (HNO₂), phosphorous acid (H₃PO₃), hydrochloric acid (HCl), acetic acid (CH₃COOH), carbonic acid (H₂CO₃), boric acid (H₂BO₃), formic acid (HCOOH), iodic acid (HIO₃), oxalic acid (H₂C₂O₄), hydrofluoric acid (HF), hydrosulfuric acid (H₂S), sulfurous acid (H₂SO₃), fluorosulfonic acid (HSO₃F), alkylsulfonic acid (RSO₃F, R═CₙH₂ₙ₊₁) or any mixture thereof, and the base including sodium hydroxide (NaOH), potassium hydroxide (KOH), calcium hydroxide (Ca(OH)₂), tetramethylammonium hydroxide (TMAH), ammonium hydroxide (NH₄OH), sodium carbonate (Na₂CO₃), sodium hydrogen carbonate (NaHCO₃), potassium carbonate (K₂CO₃), barium hydroxide (Ba(OH)₂) or any mixture thereof.

13. The method of claim 12, wherein the etching agent includes H₂O₂, KOH, TMAH or any combination thereof.

14. A method for fabricating a vertical light-emitting diode comprising:
forming a stack including a plurality of epitaxial layers on a patterned first sapphire substrate, wherein the stack has a first surface in contact with the patterned first substrate, the first surface including a pattern corresponding to a pattern provided on the first substrate;
placing a second substrate on the stack;
removing the first substrate to expose the first surface;
planarizing the first surface to remove the pattern and form a planarized second surface of the stack; and
forming a first electrode in contact with a side of the second substrate that is opposite to the stack, and
forming a second electrode in contact with the second surface and;
applying a two-stage surface treatment to roughen at least partially the second surface to form a region comprised of uneven surface portions having a geometrical shape,
wherein the one stage of two-stage surface treatment comprises:
cleaning the surface with an organic solution, and
roughening the surface by using a chemical etching agent.

15. The method of claim 14, wherein the etching agent is selected from H₂O₂, KOH, TMAH or any combination thereof.

16. The method of claim 14, wherein the organic solution is selected from acetone, methanol, isopropanol, ethanol or any combination thereof.

17. The method of claim 14, wherein the geometrical shape comprises pyramids, cones, and/or half lenticular shapes.
